(19) United States
(12) Patent Application Publication
(10) Pub. No.: US 2014/0131831 A1
(43) Pub. Date: May 15, 2014

(54) INTEGRATED CIRUIT INCLUDING AN FIN-BASED DIODE AND METHODS OF ITS FABRICATION

(71) Applicant: GLOBALFOUNDRIES, INC., Grand Cayman (KY)

(72) Inventors: Andy C. Wei, Queensbury, NY (US); Konstantin Korablev, Saratoga Springs, NY (US); Francis Tambwe, Malta, NY (US)

(73) Assignee: GLOBALFOUNDRIES, INC., Grand Cayman (KY)

(21) Appl. No.: 13/674,311

(22) Filed: Nov. 12, 2012

(51) Int. Cl. H01L 27/08; H01L 21/77

(52) U.S. Cl. CPC H01L 27/0814; H01L 21/77
USPC 257/506; 438/492; 257/E21.599; 257/E27.051

(57) ABSTRACT

A method is provided for forming an integrated circuit having a diode. The method includes forming at least one fin in a shallow trench isolation (STI) oxide layer disposed above a substrate layer. The at least one fin extends from a bottom end adjacent the substrate layer to a top end. The method further includes adding a cathode implant in a first region of the at least one fin and the substrate layer and adding an anode implant in a second region of the at least one fin and the substrate layer such that a junction is formed in the substrate layer below the at least one fin. The method also includes etching away a portion of the STI oxide layer to expose the top end of the at least one fin.

### FIELD OF THE INVENTION

The present invention generally relates to integrated circuits and more particularly relates to fin-based diodes in integrated circuits.

### BACKGROUND OF THE INVENTION

Integrated circuits may include fin-based field effect transistors (“FinFETs”). These FinFETs include non-planar structures that extend above a substrate. Typically, “fins” are formed which are utilized as sources and drains for the transistors. A gate is then disposed between, and often above, the fins.

Typically, when the integrated circuit also includes diodes, these diodes are manufactured with a conventional planar structure. This results in several disadvantages. First, there is difficulty in the chemical-mechanical planarization (“CMP”) process, due to the presence of both planar and non-planar structures. As a result, a large transition region is required between the planar region of the diodes and the non-planar region of the FinFETs. As such, critical space on the integrated circuit is wasted.

Also, the process for forming the sources and drains of the non-planar FinFETs is different from the process for forming the cathodes and anodes of the planar diodes. Accordingly, additional time-consuming steps are required in the manufacture of a typical FinFET integrated circuit.

Furthermore, a different etch process for forming landing contacts on a non-planar FinFET is different from that of a planar diode. Again, additional time consuming steps are required in typical FinFET integrated circuits.

Accordingly, it is desirable to produce a FinFET integrated circuit which includes non-planar fin-based diodes. Other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method is provided for forming a diode. The method includes forming at least one fin in a shallow trench isolation (STI) oxide layer disposed above a substrate layer. The at least one fin extends from a bottom end adjacent the substrate layer to a top end. The method further includes adding a cathode implant in a first region of the at least one fin and the substrate layer and adding an anode implant in a second region of the at least one fin and the substrate layer such that a junction is formed in the substrate layer below the at least one fin. The method also includes etching away a portion of the STI oxide layer to expose the top end of the at least one fin.

### BRIEF DESCRIPTION OF THE DRAWINGS

The present invention will hereinafter be described in conjunction with the following drawing figures, wherein like numerals denote like elements, and

FIG. 1 shows a partial top view of one embodiment of an integrated circuit showing diodes and transistors;

FIG. 2 shows a partial cross-sectional side view of one embodiment of the integrated circuit illustrating a plurality of fins disposed in an oxide above a substrate along the line 2-2 in FIG. 3;

FIG. 3 shows a partial top view of the integrated circuit illustrating the plurality of fins disposed in the oxide;

FIG. 4 shows a partial cross-sectional side view of the integrated circuit after forming an n-well in the substrate;

FIG. 5 shows a partial cross-sectional side view of the integrated circuit after adding a cathode implant and an anode implant;

FIG. 6 shows a partial cross-sectional side view of the integrated circuit after etching away a portion of the oxide to expose a top end of the fins;

FIG. 7 shows a partial cross-sectional side view of the integrated circuit after epitaxially growing a semiconductor material on the top end of the exposed fins;

FIG. 8 shows a top view of the integrated circuit after disposing a plurality of dummy gates and self-aligned contacts above the fins;

FIG. 9 shows a partial cross-sectional side view of the integrated circuit after implanting a p-well in the substrate;

FIG. 10 shows a partial top view of another embodiment of a integrated circuit illustrating a plurality of fins with each fin forming a diode; and

FIG. 11 shows a partial cross-sectional side view of the integrated circuit one fin forming the diode along the line 11-11 in FIG. 10.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Methods of forming a diode 50 are described herein. In the described embodiments, the diode 50 is one of a plurality of diodes 50 formed together during a common fabrication process. However, for purposes of simplicity and clarity, the plurality of diodes may be referred to simply as a single diode 50.

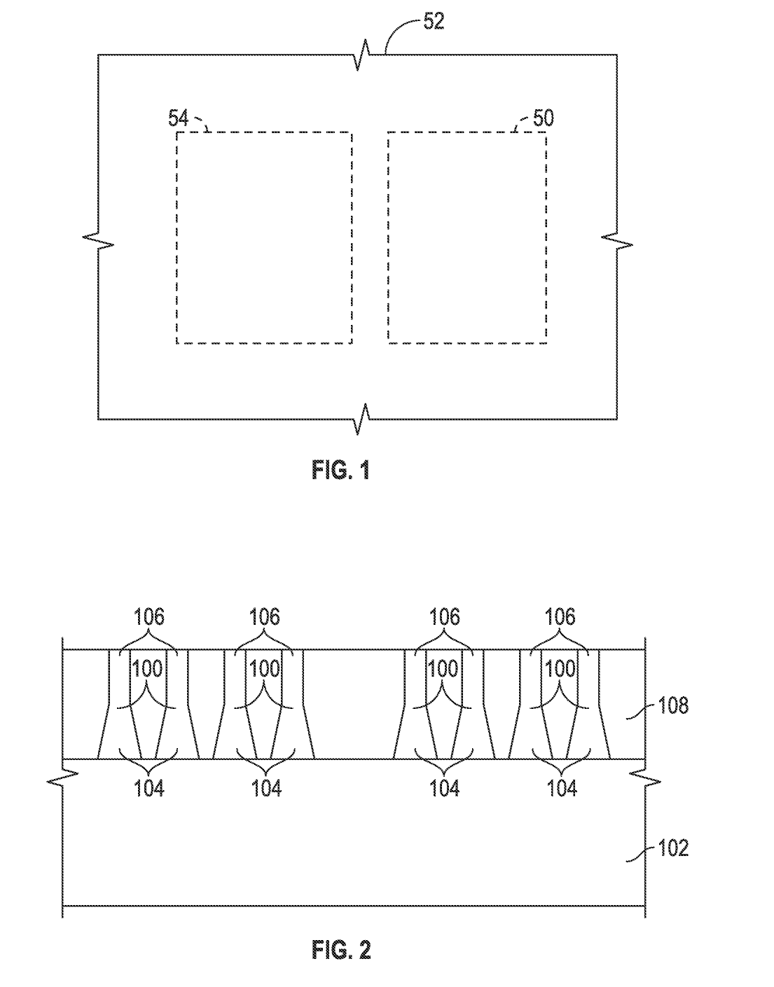

With reference to FIG. 1, the diodes 50 may be a component of an integrated circuit 52. The integrated circuit 52 may include transistors 54. Specifically, the integrated circuit 52 of the illustrated embodiment includes metal-oxide-silicon field effect transistors (“MOSFETs”) (not separately numbered). More specifically, the MOSFETs of the integrated circuit 52 may have a fin-based architecture. As such, the MOSFETs may be referred to as “FinFETs”, as is appreciated by those skilled in the art.

Referring now to FIG. 2 an embodiment of a method of forming the diode 50 includes forming at least one fin. Specifically, in the embodiments shown in FIGS. 2-11 a plurality of fins 100 are formed. Each fin 100 is an elongated structure that extends “upward” from a semiconductor substrate 102 between a bottom end 104 to a top end 106. The bottom end 104 is disposed adjacent to the substrate layer 102. The substrate layer 102 in the illustrated embodiment is a p-type substrate or simply a “p-substrate”. However, those skilled in the art realize that the substrate layer 102 may alternative be an n-type substrate.

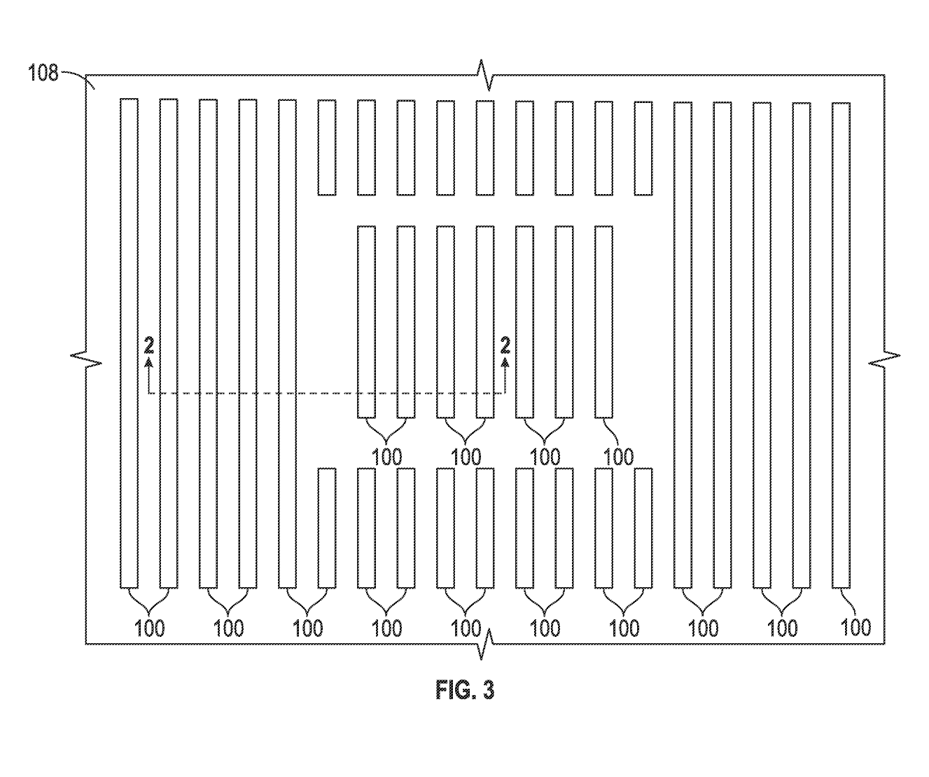

In the illustrated embodiments, the fins 100 are formed in a shallow trench isolation (“STI”) oxide 108. As can be seen with reference to FIGS. 2 and 3, the fins 100 are embedded within the oxide 108. The fins 100 may be formed by etching a substrate to form the fins 100. The spaces between the fins 100 are then filled with the oxide 108. Excess oxide 108 may be removed by planarization. In the illustrated embodiment, the semiconductor material forming the fins 100 is silicon. However, other materials may alternatively be utilized.

In the illustrated embodiment, the width of the top end 106 of each fin 100 may be between 5 nanometers (“nm”) and 15 nm. The width of bottom end 104 of each fin 100 may be up to the fin pitch, i.e., the width between each fin 100. However, in other embodiments, differing dimensions may also be acceptable.

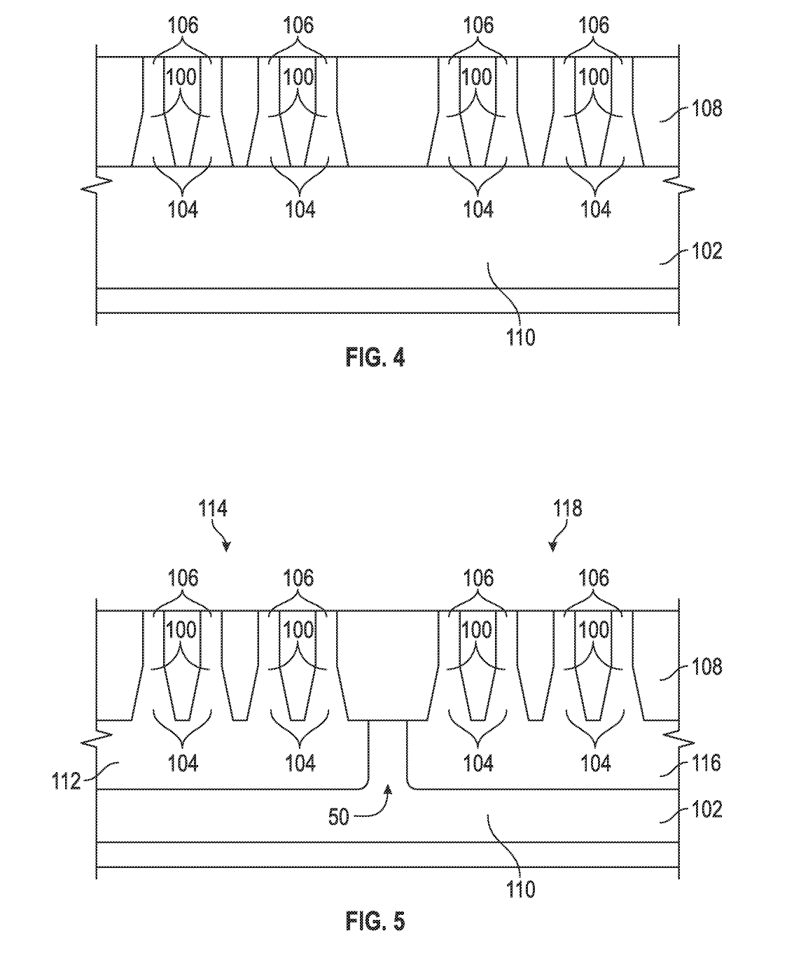

Referring to FIG. 4, the method further includes forming an n-well 110 in the substrate layer 102. As such, the n-well 110 is disposed in the substrate layer 102 below the bottom ends 104 of the fins 100. Techniques for forming the n-well 110 in the substrate 102 are well known to those skilled in the art and include ion implantation.

Referring now to FIG. 5, the method also includes adding a cathode 112 implant in a first region 114 of the fins 100. That is, a cathode 112 is formed using ion implantation techniques. Specifically, the cathode 112 is formed by n+ doping the first region 114 using ion implantation. As such, the cathode 112 implant may also be referred to as a n+ implant. The method also includes adding an anode 116 implant in a second region 118 of the fins 100. That is, an anode 116 is formed using ion implantation techniques. Specifically, the anode 116 is formed by p+ doping the second region 118 using ion implantation. As such, the anode 116 implant may also be referred to as a p+ implant. By forming the cathode 112 and anode 114 using ion implantation techniques, a p-n junction (not numbered) of the diode 50 is formed between the cathode 112 and anode 114 implants in the semiconductor substrate 102 below the bottom ends 104 of at least some of the fins 100.

The cathode 112 and anode 116 implants extend relatively deep into the substrate 102, especially when compared to prior art fin-based and planar diodes. Furthermore, the cathode 112 and anode 116 implants form a low-resistance path from the top end 106 to the bottom end 104 of each fin 100.

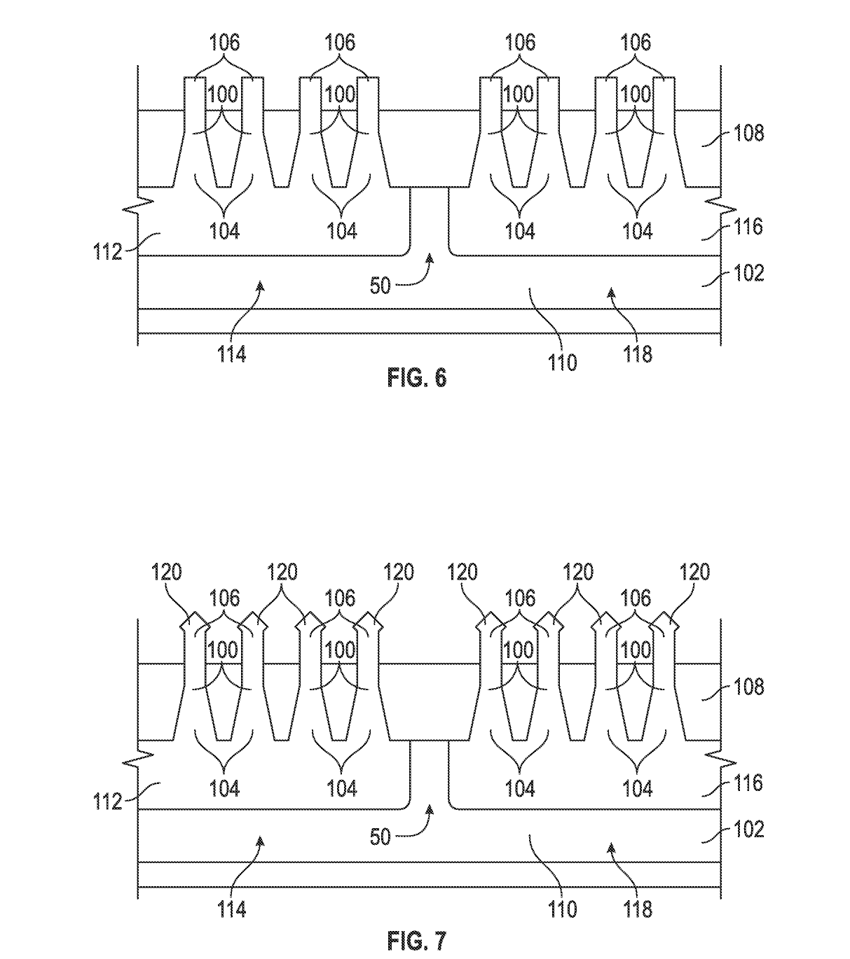

Referring now to FIG. 6, the method further includes etching away a portion of the STI oxide layer 108 to expose the top end 106 of at least some of the fins 100. Said another way, the fins 100 are revealed by etchback of the STI oxide layer 108. Numerous techniques for etching the STI oxide layer 108 including wet etching and dry (i.e., plasma) etching techniques. In the illustrated embodiments, the etching of the STI oxide layer 108 occurs after adding the cathode 112 implant and the anode 116 implant.

With reference to FIG. 7, the method also includes epitaxially growing a semiconductor material 120 on the top end 106 of at least one of the exposed fins 100. That is, the fins 100 undergo an epi process. Techniques for epitaxially growing the semiconductor material 120 are well known to those skilled in the art and include, but are not limited to, molecular beam epitaxy and chemical vapor deposition. The epi process for the exposed fins 100 of the diodes may be done with the same epi process that is utilized in the manufacture of the source and drains of the FinFETs 54 of the integrated circuit 52. Accordingly, a separate procedure does not need to be established for the diodes 50 of the integrated circuit 54.

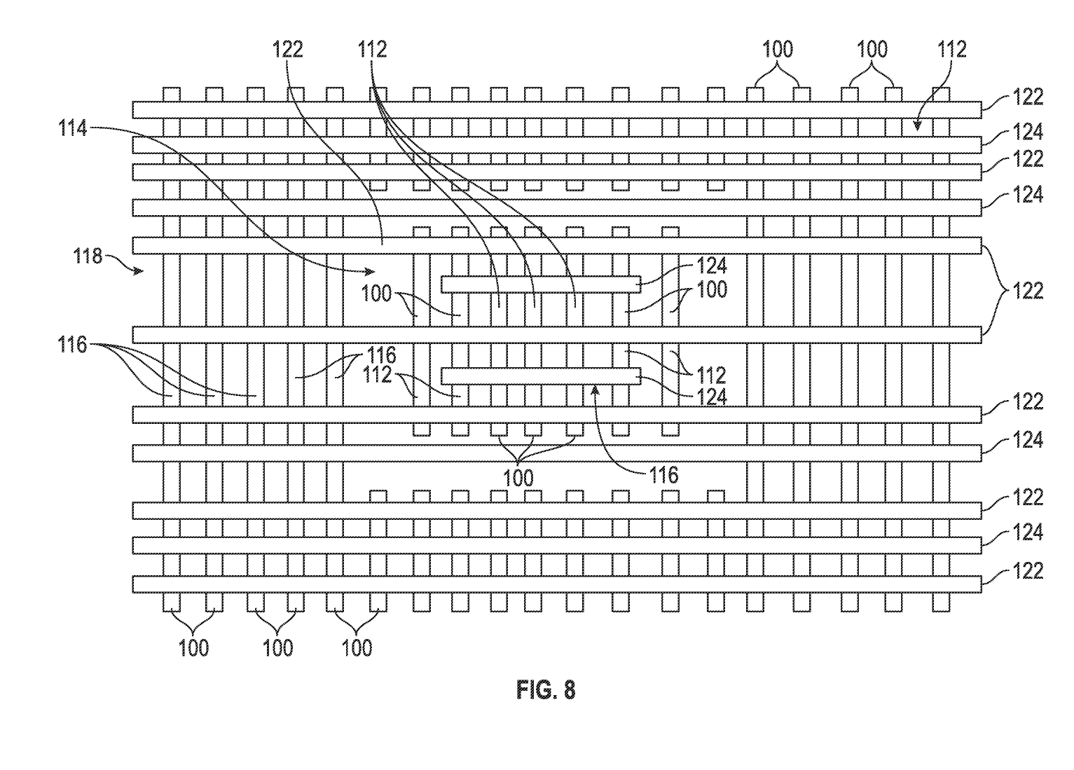

Referring now to FIG. 8, the method may further include disposing a dummy gate 122 above the top end 106 of at least one of the fins 100. More specifically, a plurality of dummy gates 122 may be tiled above the cathode 112 and anode 116 implants. By utilizing the dummy gates 122, chemical mechanical polishing (“CMP”) performance is improved during replacement metal gate (“RMG”) processing of the integrated circuit. Those skilled in the art appreciate that RMG processing may be utilized in the production of the MOSFETs to provide to provide gates for the MOSFETs. The utilization of dummy gates 122 may also improve other planarization steps utilized in the manufacture of the integrated circuit.

The method may also include disposing a self-aligned contact (“SAC”) 124 in contact with the top end 106 with at least one of the fins 100. In one embodiment, the SAC 124 may be disposed on the top end 106 of a plurality of cathode 112 implanted fins 100, as shown in FIG. 7. Disposing the SAC 124 in contact with the cathode 112 implanted fins 100 assists in creating a high ideality diode. The SAC 124 may also be disposed in contact with the anode 114 implanted fins 100. A plurality of SACs 124 may be utilized, as shown in FIG. 8.

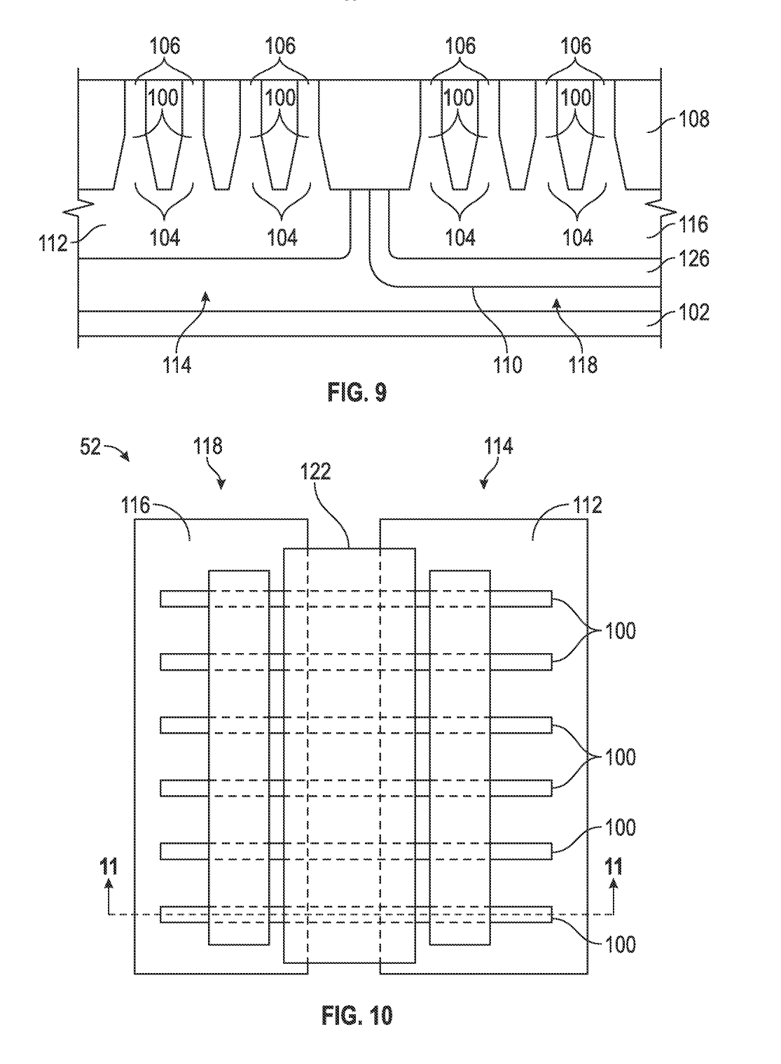

A method of forming a diode 50 may also include forming a well tap 126 below the fins 100. In one embodiment, as shown in FIG. 9, the well tap 126 is formed by implanting a p-well (not separately numbered) in the substrate 102. Specifically, the p-well 16 is formed in the second region 118 below the bottom end 104 of at least some of the fins 100. The step of implanting the well tap in the substrate 102 may be performed prior to the step of etching away a portion of the STI oxide layer 108. Furthermore, this step of implanting the well tap 126 may be performed concurrently with the adding of the anode 112 and/or cathode 116 implant. As such, a separate masking step is not needed for implanting the well tap 126.

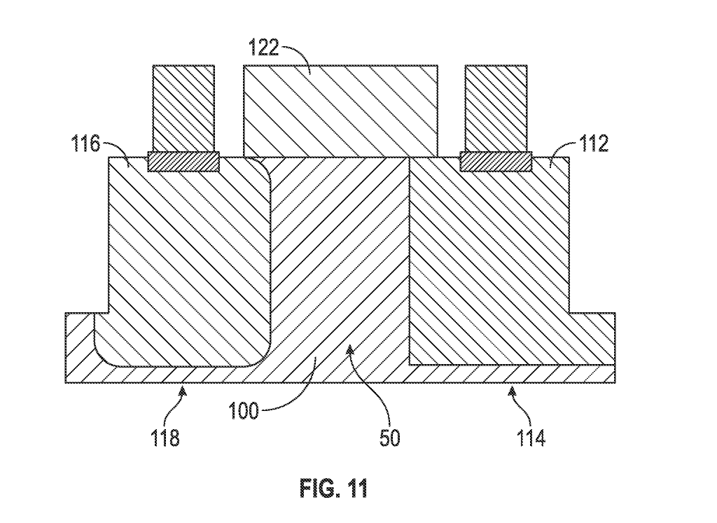

The embodiments shown in FIGS. 2-9 generally show a plurality of fins 100 being utilized to form each diode 50. However, a single fin 100 may be utilized to realize a single diode 50. With reference to FIGS. 10 and 11, another embodiment of the integrated circuit 52 shows each fin 100 being divided into the first region 114 and the second region 118. Accordingly, the cathode 112 implant is formed in the first region 114 and the anode 116 implant is formed in the second region.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method of forming a diode, comprising:
forming at least one fin in a shallow trench isolation (STI) oxide layer disposed above a substrate layer, the at least one fin extending from a bottom end adjacent the substrate layer to a top end;
adding a cathode implant in a first region of the at least one fin and the substrate layer and adding an anode implant in a second region of the at least one fin and the substrate layer such that a junction is formed in the substrate layer below the at least one fin; and
etching away a portion of the STI oxide layer to expose the top end of the at least one fin.

2. A method as set forth in claim 1 further comprising forming an n-well in the substrate layer below the bottom end of the at least one fin.

3. A method as set forth in claim 2 wherein said forming an n-well is performed prior to said adding a cathode implant and said adding an anode implant.

4. A method as set forth in claim 1 wherein said etching away a portion of the STI oxide layer occurs after adding the cathode implant and the anode implant.

5. A method as set forth in claim 1 further comprising forming a well tap below the at least one fin.

6. A method as set forth in claim 5 wherein said forming a well tap is further defined as implanting a p-well in the substrate in the first region below the bottom end of the at least one fin.

7. A method as set forth in claim 6 wherein said implanting a p-well and said adding a cathode implant are performed concurrently.

8. A method as set forth in claim 1 further comprising epitaxially growing a semiconductor material on the exposed top end of the at least one fin.

9. A method as set forth in claim 1 further comprising disposing a dummy gate above the top end of the at least one fin.

10. A method as set forth in claim 1 further comprising disposing a self-aligning contact above the top end of the at least one fin.

11. A method of fabricating an integrated circuit, comprising:
establishing at least one FinFET on a substrate layer;
establishing at least one diode including
forming at least one fin in a shallow trench isolation (STI) oxide layer disposed above the substrate layer, the at least one fin extending from a bottom end adjacent the substrate layer to a top end;
adding a cathode implant in a first region of the at least one fin and the substrate layer and adding an anode implant in a second region of the at least one fin and the substrate layer such that a junction is formed in the substrate layer below the at least one fin; and
etching away a portion of the STI oxide layer to expose the top end of the at least one fin.

12. A method as set forth in claim 11 further comprising forming an n-well in the substrate layer below the bottom end of the at least one fin.

13. A method as set forth in claim 12 wherein said forming an n-well is performed prior to said adding a cathode implant and said adding an anode implant.

14. A method as set forth in claim 11 wherein said etching away a portion of the STI oxide layer occurs after adding the cathode implant and the anode implant.

15. A method as set forth in claim 11 further comprising forming a well tap below the at least one fin.

16. A method as set forth in claim 15 wherein said forming a well tap is further defined as implanting a p-well in the substrate in the first region below the bottom end of the at least one fin.

17. A method as set forth in claim 16 wherein said implanting a p-well and said adding a cathode implant are performed concurrently.

18. An integrated circuit including a semiconductor diode, said diode comprising:
a substrate layer;
a shallow trench isolation (STI) oxide layer disposed above said substrate layer;
at least one fin disposed at least partially in the STI oxide layer, the at least one fin extending from a bottom end to a top end;
a cathode implant formed in a first region of said at least one fin and extending into said substrate below said at least one fin; and
an anode implant formed in a second region of said at least one fin and extending into said substrate below said at least one fin such that a junction is formed in said substrate below said at least one fin.

19. An integrated circuit as set forth in claim 18 further comprising a well tap formed in the substrate layer below said at least one fin.
